(19) United States
(12) Patent Application Publication
(10) Pub. No.: US 2025/0140552 A1
(43) Pub. Date: May 1, 2025

(54) SUBSTRATE PROCESSING METHOD AND SUBSTRATE PROCESSING APPARATUS

(71) Applicant: Tokyo Electron Limited, Tokyo (JP)

(72) Inventors: Motoki SHINDEN, Iwate (JP); Yukio TOJO, Iwate (JP); Yoichiro CHIBA, Iwate (JP); Masaki KUROKAWA, Iwate (JP)

(21) Appl. No.: 18/923,883

(22) Filed: Oct. 23, 2024

(30) Foreign Application Priority Data
Oct. 30, 2023 (JP) 2023-185822

(51) Int. Cl. H01L 21/02; H01L 21/67

(52) U.S. Cl. CPC H01L 21/02337; C23C 14/0652; H01L 21/0217; H01L 21/67109

(57) ABSTRACT

A technique capable of increasing the deuterium concentration in an insulating film is provided. A substrate processing method according to an aspect of the present disclosure includes preparing a substrate having an insulating film on a surface thereof, raising the temperature of the substrate from a first temperature to a second temperature higher than the first temperature, and maintaining the substrate at the second temperature. Raising of the temperature to the second temperature includes supplying either gas or both gases selected from deuterium gas and hydrogen gas to the substrate, and maintaining of the substrate at the second temperature includes supplying a deuterium gas to the substrate.

### CROSS-REFERENCE TO RELATED APPLICATION

The present application claims priority under 35 U.S.C. § 119 to Japanese Patent Application No. 2023-185822, filed Oct. 30, 2023, the contents of which are incorporated herein by reference in their entireties.

### BACKGROUND OF THE INVENTION

### Field of the Invention

This disclosure relates to a substrate processing method and a substrate processing apparatus.

### Description of the Related Art

A technique for bringing deuterium to be contained at an interface between a semiconductor substrate and a gate insulating film formed on the semiconductor substrate at a ratio greater than a ratio at which deuterium and hydrogen exist in nature is known (for example, see Japanese Patent Application Laid-Open Publication No. 2000-77621).

### SUMMARY OF THE INVENTION

The present disclosure provides a technique enabling increasing the deuterium concentration in an insulating film.

A substrate processing method according to an aspect of the present disclosure includes: preparing a substrate having an insulating film on a surface thereof; raising a temperature of the substrate from a first temperature to a second temperature higher than the first temperature; and maintaining the substrate at the second temperature, wherein the raising of the temperature to the second temperature includes supplying either gas or both gases selected from a deuterium gas and a hydrogen gas to the substrate, and the maintaining of the substrate at the second temperature includes supplying a deuterium gas to the substrate.

According to the present disclosure, the deuterium concentration in an insulating film can be increased.

### BRIEF DESCRIPTION OF THE DRAWINGS

FIG. 1 is a flowchart illustrating a substrate processing method according to an embodiment;

FIG. 2 is a timing chart illustrating a first example of a substrate processing method according to an embodiment;

FIG. 3 is a timing chart illustrating a second example of a substrate processing method according to an embodiment;

FIG. 4 is a timing chart illustrating a third example of a substrate processing method according to an embodiment;

FIG. 5 is a timing chart illustrating a fourth example of a substrate processing method according to an embodiment;

FIG. 6 is a schematic cross-sectional view illustrating a substrate processing apparatus according to an embodiment;

FIG. 7 is a graph (1) illustrating the result of measuring the deuterium concentration in a silicon nitride film; and

FIG. 8 is a graph (2) illustrating the result of measuring the deuterium concentration in a silicon nitride film.

### DETAILED DESCRIPTION OF THE DISCLOSURE

Non-limiting example embodiments of the present disclosure will now be described with reference to the accompanying drawings. In all the accompanying drawings, the same or corresponding members or parts will be denoted by the same or corresponding reference numerals, and duplicate descriptions will be omitted.

### [Substrate Processing Method]

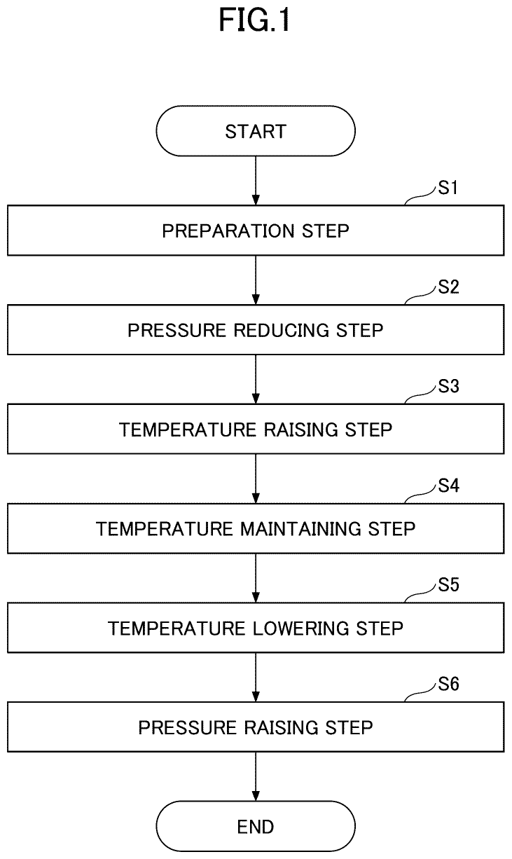

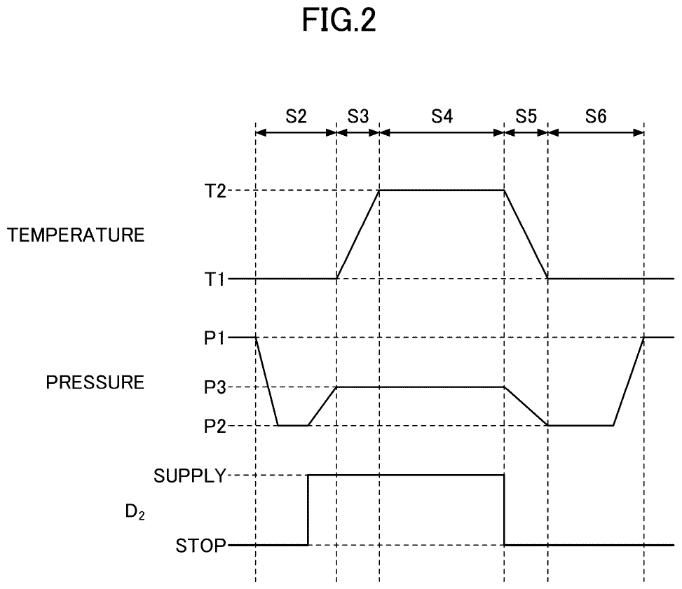

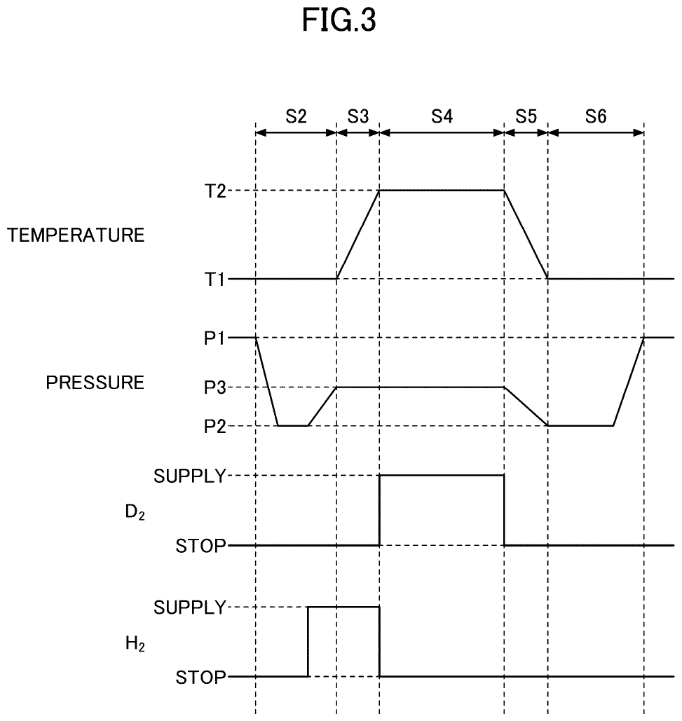

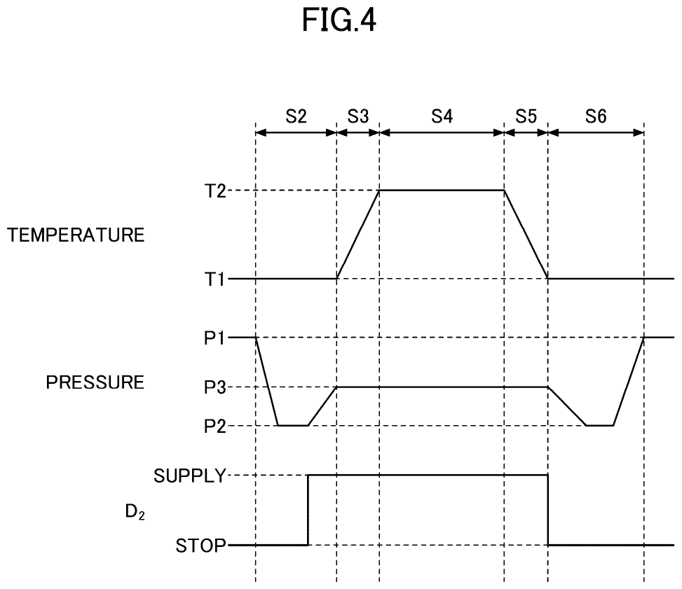

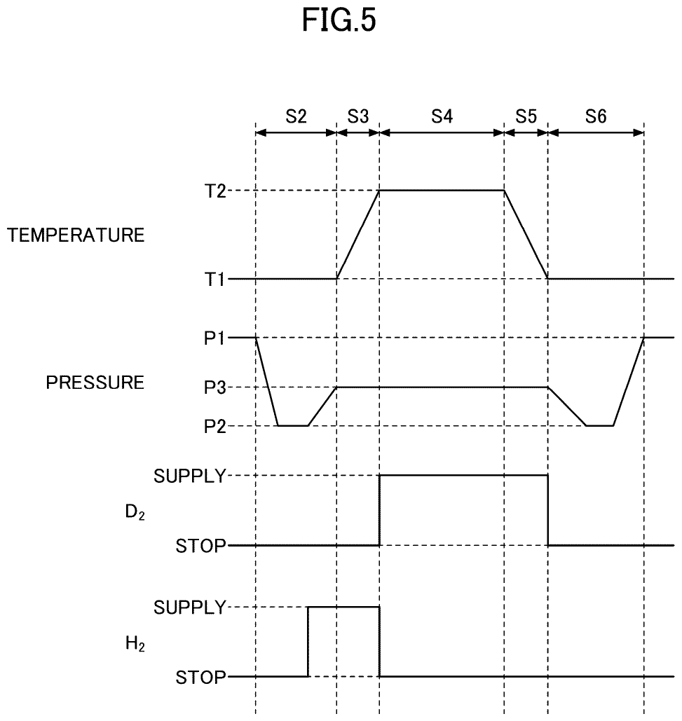

A substrate processing method according to an embodiment will now be described with reference to FIGS. 1 to 5. FIG. 1 is a flowchart illustrating a substrate processing method according to an embodiment. FIG. 2 is a timing chart illustrating a first example of the substrate processing method according to the embodiment. FIG. 3 is a timing chart illustrating a second example of the substrate processing method according to the embodiment. FIG. 4 is a timing chart illustrating a third example of the substrate processing method according to the embodiment. FIG. 5 is a timing chart illustrating a fourth example of the substrate processing method according to the embodiment. FIGS. 2 to 5 indicate the temperature of the substrate, the pressure in the processing chamber, supply and stop of deuterium (D₂) gas, and supply and stop of hydrogen (H₂) gas in each step of the substrate processing method according to the embodiment.

As illustrated in FIG. 1, the substrate processing method according to the embodiment includes a preparation step S1, a pressure reducing step S2, a temperature raising step S3, a temperature maintaining step S4, a temperature lowering step S5, and a pressure raising step S6.

The preparation step S1 includes preparing a substrate having a silicon nitride film on a surface thereof. The preparation step S1 includes accommodating the substrate in a processing chamber that can be depressurized by an exhaust device. The substrate is, for example, a semiconductor wafer. The silicon nitride film may contain hydrogen atoms (H) in the film. The silicon nitride film may contain N—H bonds in the film.

The pressure reducing step S2 is performed after the preparation step S1. The pressure reducing step S2 includes reducing the pressure in the processing chamber from a first pressure P1 to a second pressure P2, as illustrated in FIGS. 2 to 5. The first pressure P1 is, for example, an open-air pressure. The second pressure P2 is, for example, a base pressure. The base pressure is, for example, the highest degree of vacuum attainable with the maximum exhaust capacity of the exhaust device.

The pressure reducing step S2 may include maintaining the substrate at a first temperature T1 as illustrated in FIGS. 2 to 5. The first temperature T1 is, for example, 750° C. or less. This facilitates inhibition of desorption of hydrogen atoms contained in the silicon nitride film. The first temperature T1 may be 650° C. or less. This particularly facilitates inhibition of desorption of hydrogen atoms contained in the silicon nitride film. Inhibition of desorption of hydrogen atoms contained in the silicon nitride film facilitates introduction of deuterium atoms in the temperature maintaining step S4. This is because deuterium atoms are considered to be introduced into the silicon nitride film by the hydrogen atoms contained in the silicon nitride film being replaced with deuterium atoms in the temperature maintaining step S4.

The pressure reducing step S2 may include starting deuterium gas supply from a point in time during the step and continuing deuterium gas supply until the end of the step, as illustrated in FIGS. 2 and 4. The pressure reducing step S2 may include starting hydrogen gas supply from a point in time during the step and continuing hydrogen gas supply until the end of the step, as illustrated in FIGS. 3 and 5. The pressure reducing step S2 may include starting supply of a mixed gas of deuterium gas and hydrogen gas from a point in time during the step and continuing supply of the mixed gas until the end of the step. By either or both of deuterium gas and hydrogen gas being supplied in the pressure reducing step S2, the pressure in the processing chamber is raised from the second pressure P2 to the third pressure P3.

The temperature raising step S3 is performed after the pressure reducing step S2. The temperature raising step S3 includes raising the temperature of the substrate from the first temperature T1 to a second temperature T2 as illustrated in FIGS. 2 to 5. The second temperature T2 is a temperature higher than the first temperature T1.

The temperature raising step S3 includes supplying deuterium gas to the substrate as illustrated in FIGS. 2 and 4. In this case, deuterium atoms are introduced into the silicon nitride film. The temperature raising step S3 may include supplying hydrogen gas to the substrate as illustrated in FIGS. 3 and 5. This inhibits desorption of hydrogen atoms contained in the silicon nitride film. Inhibition of desorption of hydrogen atoms contained in the silicon nitride film facilitates introduction of deuterium atoms in the temperature maintaining step S4. This is because deuterium atoms are considered to be introduced into the silicon nitride film by the hydrogen atoms contained in the silicon nitride film being replaced with deuterium atoms in the temperature maintaining step S4. Since hydrogen gas is cheaper than deuterium gas, it is possible to introduce deuterium atoms into the silicon nitride film at a low cost. The temperature raising step S3 may include supplying a mixed gas of deuterium gas and hydrogen gas to the substrate. In this case, deuterium atoms are introduced into the silicon nitride film and desorption of hydrogen atoms contained in the silicon nitride film is inhibited. On the other hand, when neither deuterium gas nor hydrogen gas is supplied to the substrate in the temperature raising step S3, hydrogen atoms contained in the silicon nitride film become likely to desorb as the temperature of the substrate rises. This makes it difficult to introduce deuterium atoms into the silicon nitride film at a high concentration.

As illustrated in FIGS. 2 and 4, deuterium gas may be supplied to the substrate before the start of the temperature raising step S3, in other words, continuously from the pressure reducing step S2. This facilitates a high-concentration introduction of deuterium atoms into the silicon nitride film. The deuterium gas may be supplied to the substrate from the start of the temperature raising step S3, or may be supplied to the substrate from a point in time during the temperature raising step S3. As illustrated in FIGS. 2 and 4, the deuterium gas may be continuously supplied to the substrate throughout the entire period of the temperature raising step S3. This facilitates a high-temperature introduction of deuterium atoms into the silicon nitride film.

As illustrated in FIGS. 3 and 5, the hydrogen gas may be supplied to the substrate before the start of the temperature raising step S3, in other words, continuously from the pressure reducing step S2. This facilitates inhibition of desorption of hydrogen atoms contained in the silicon nitride film. The hydrogen gas may be supplied to the substrate from the start of the temperature raising step S3, or may be supplied to the substrate from a point in time during the temperature raising step S3. As illustrated in FIGS. 3 and 5, the hydrogen gas may be supplied to the substrate continuously throughout the entire period of the temperature raising step S3. This particularly facilitates inhibition of desorption of hydrogen atoms contained in the silicon nitride film.

The temperature maintaining step S4 is performed after the temperature raising step S3. The temperature maintaining step S4 includes maintaining the substrate at the second temperature T2 as illustrated in FIGS. 2 to 5. The temperature maintaining step S4 includes supplying deuterium gas to the substrate. In this case, deuterium atoms are introduced into the silicon nitride film by hydrogen atoms contained in the silicon nitride film being replaced with deuterium atoms. The deuterium gas may be continuously supplied to the substrate throughout the entire period of the temperature maintaining step S4 as illustrated in FIGS. 2 to 5. This facilitates a high-concentration introduction of deuterium atoms into the silicon nitride film.

The second temperature T2 is, for example, 500° C. or higher. This facilitates replacement of hydrogen atoms contained in the silicon nitride film with deuterium atoms. The second temperature T2 may be 800° C. or higher. This particularly facilitates replacement of hydrogen atoms contained in the silicon nitride film with deuterium atoms. The second temperature T2 is, for example, 1,000° C. or lower. This facilitates inhibition of desorption of deuterium atoms contained in the silicon nitride film. The second temperature T2 may be 900° C. or lower. This particularly facilitates inhibition of desorption of deuterium atoms contained in the silicon nitride film.

The temperature lowering step S5 is performed after the temperature maintaining step S4. As illustrated in FIGS. 2 to 5, the temperature lowering step S5 includes lowering the temperature of the substrate from the second temperature T2 to the first temperature T1. As illustrated in FIGS. 2 and 3, the temperature lowering step S5 may include depressurizing the interior of the processing chamber by an exhaust device without supplying deuterium gas and hydrogen gas to the substrate. The temperature lowering step S5 may include supplying deuterium gas to the substrate as illustrated in FIGS. 4 and 5. This facilitates inhibition of desorption of deuterium atoms contained in the silicon nitride film in the temperature lowering step S5. The deuterium gas may be continuously supplied to the substrate throughout the entire period of the temperature lowering step S5 as illustrated in FIGS. 4 and 5. This particularly facilitates inhibition of desorption of deuterium atoms contained in the silicon nitride film.

The pressure raising step S6 is performed after the temperature lowering step S5. The pressure raising step S6 includes raising the pressure in the processing chamber from the second pressure P2 to the first pressure P1 as illustrated in FIGS. 2 to 5. The pressure raising step S6 includes raising the pressure in the processing chamber from the second pressure P2 to the first pressure P1 by, for example, supplying an inert gas into the processing chamber without supplying deuterium gas and hydrogen gas to the substrate as illustrated in FIGS. 2 to 5. After the pressure in the processing chamber is raised from the second pressure P2 to the first pressure P1, the substrate is removed from the processing chamber.

As described above, according to the substrate processing method of the embodiment, the temperature raising step S3 and the temperature maintaining step S4 are performed in this order. The temperature raising step S3 includes supplying either or both of deuterium gas and hydrogen gas to the substrate. The temperature maintaining step S4 includes supplying deuterium gas to the substrate. This can increase the deuterium concentration in the silicon nitride film. This is considered to be because inhibition of desorption of hydrogen atoms contained in the silicon nitride film in the temperature raising step S3, improves the efficiency at which hydrogen atoms contained in the silicon nitride film are replaced with deuterium atoms in the temperature maintaining step S4.

### [Substrate Processing Apparatus]

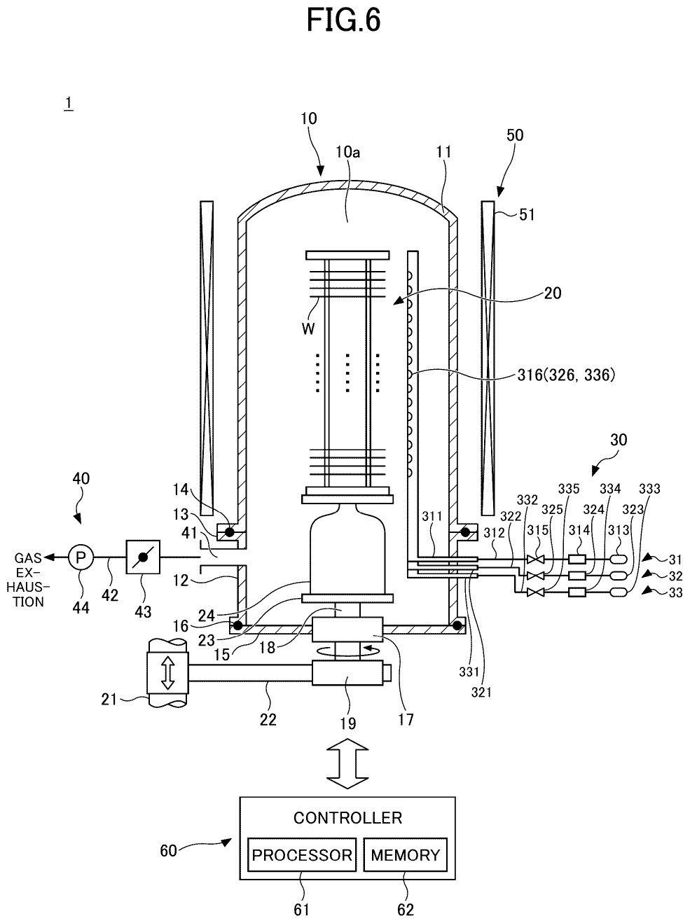

A substrate processing apparatus 1 according to an embodiment will be described with reference to FIG. 6. As illustrated in FIG. 6, the substrate processing apparatus 1 includes a processing chamber 10, a boat 20, a gas supply 30, an exhauster 40, a heater 50, and a controller 60.

The processing chamber 10 has a cylindrical shape having a processing space 10a therein. The processing chamber 10 performs heat treatment while a substrate W is accommodated in the processing space 10a. The processing chamber 10 has a cylindrical body 11 having a substantially hemispherical ceiling while being open at the lower end, a manifold 12 connected to the lower end of the cylindrical body 11, and a cap 15 connected to the lower end of the manifold 12.

The cylindrical body 11 is made of a heat-resistant material such as quartz or the like. The cylindrical body 11 extends long in the vertical direction (height direction) and constitutes a major part of the processing space 10a of the processing chamber 10. Although FIG. 6 illustrates a configuration in which the processing chamber 10 has one cylindrical body 11, the configuration is not limited to this. For example, the processing chamber 10 may have a multiple structure in which a plurality of cylinders (outer cylinder and inner cylinder) are concentrically arranged.

The manifold 12 and the cap 15 are made of, for example, stainless steel. The manifold 12 has a flange 13 at an upper end, and the lower end of the cylindrical body 11 is supported by the flange 13. The lower end of the cylindrical body 11 and the flange 13 are hermetically joined via a sealing member 14 such as an O-ring or the like. Similarly, the lower end of the manifold 12 and the cap 15 are brought into a hermetical contact via a sealing member 16 such as an O-ring or the like.

A rotating shaft 18 penetrates the center of the cap 15 via a magnetic fluid seal 17. The rotating shaft 18 has the boat 20 on an upper part thereof, and is connected to a rotation drive part 19 and rotates relative to the processing chamber 10 by rotation of the rotation drive part 19. As a result, the boat 20 rotates.

The lower part of the rotating shaft 18 is rotatably supported by an arm 22 of an elevating mechanism 21 such as a boat elevator. A rotating plate 23 is provided at the upper end of the rotating shaft 18, and the boat 20 is mounted on the rotating plate 23 via a heat insulation table 24 made of quartz. Therefore, the cap 15 and the boat 20 move up and down integrally by the elevating mechanism 21 being moved up or down, such that the boat 20 can be accommodated in and removed from the cylindrical body 11.

The boat 20 is a substrate holder extending in the vertical direction (height direction) in the processing chamber 10 and configured to hold a plurality of substrates W at predetermined intervals along the vertical direction. The substrates W are mounted on the boat 20 in a state that the boat is removed from the processing chamber 10 by downward moving of the elevating mechanism 21. After being mounted with the substrates W, the boat 20 is inserted into the processing chamber 10 by upward moving of the elevating mechanism 21.

The gas supply 30 can introduce various process gases used in the substrate processing method described above into the processing space 10a. The gas supply 30 includes a deuterium supply 31, a hydrogen supply 32, and an inert gas supply 33.

The deuterium supply 31 includes a deuterium supply pipe 311 in the processing chamber 10 and a deuterium supply path 312 outside the processing chamber 10. The deuterium supply path 312 is provided with a deuterium source 313, a mass flow controller 314, and a deuterium valve 315 in an order from an upstream side to a downstream side in the gas flow direction. Thus, the deuterium valve 315 controls the supply timing of the deuterium gas of the deuterium source 313, and the mass flow controller 314 adjusts the deuterium gas to a predetermined flow rate. The deuterium gas flows into the deuterium supply pipe 311 from the deuterium supply path 312 and is discharged into the processing chamber 10 from the deuterium supply pipe 311.

The hydrogen supply 32 includes a hydrogen supply pipe 321 in the processing chamber 10 and a hydrogen supply path 322 outside the processing chamber 10. The hydrogen supply path 322 is provided with a hydrogen source 323, a mass flow controller 324, and a hydrogen valve 325 in an order from an upstream side to a downstream side in the gas flow direction. Thus, the hydrogen valve 325 controls the supply timing of the hydrogen gas of the hydrogen source 323, and the mass flow controller 324 adjusts the hydrogen gas to a predetermined flow rate. The hydrogen gas flows into the hydrogen supply pipe 321 from the hydrogen supply path 322 and is discharged into the processing chamber 10 from the hydrogen supply pipe 321.

The inert gas supply 33 includes an inert gas supply pipe 331 in the processing chamber 10 and an inert gas supply path 332 outside the processing chamber 10. The inert gas supply path 332 is provided with an inert gas source 333, a mass flow controller 334, and an inert gas valve 335 in an order from an upstream side to a downstream side in the gas flow direction. Thus, the inert gas valve 335 controls the supply timing of the inert gas of the inert gas source 333, and the mass flow controller 334 adjusts the inert gas to a predetermined flow rate. The inert gas flows into the inert gas supply pipe 331 from the inert gas supply path 332 and is discharged from the inert gas supply pipe 331 into the processing chamber 10. The inert gas is, for example, argon gas. The inert gas may be nitrogen gas.

Each gas supply pipe (the deuterium supply pipe 311, the hydrogen supply pipe 321, and the inert gas supply pipe 331) is made of, for example, quartz. Each gas supply pipe is fixed to the cylindrical body 11 or the manifold 12. Each gas supply pipe extends linearly in the vertical direction at a position near the cylindrical body 11, and bends in an L-letter shape in the manifold 12 and extends in the horizontal direction to thereby penetrate the manifold 12. The respective gas supply pipes are arranged side by side along the circumferential direction of the cylindrical body 11, and are formed at the same height.

A plurality of deuterium discharge ports 316 are provided at a part of the deuterium supply pipe 311 that is positioned in the cylindrical body 11. A plurality of hydrogen discharge ports 326 are provided at a part of the hydrogen supply pipe 321 that is positioned in the cylindrical body 11. A plurality of inert gas discharge ports 336 are provided at a part of the inert gas supply pipe 331 that is positioned in the cylindrical body 11.

The discharge ports of each type (the deuterium discharge ports 316, the hydrogen discharge ports 326, and the inert gas discharge ports 336) are formed at predetermined intervals along the extending direction of the gas supply pipe. The discharge ports discharge gas in the horizontal direction. The interval between the discharge ports is set to be, for example, the same as the interval between the substrates W held on the boat 20. The position of each discharge port in the height direction is set at a middle position between the substrates W adjacent to each other in the vertical direction. Thus, the discharge ports can efficiently supply gas to the facing surfaces of the substrates W adjacent to each other.

The gas supply 30 may mix a plurality of types of gases and discharge the mixed gases from one supply pipe. The respective gas supply pipes (the deuterium supply pipe 311, the hydrogen supply pipe 321, and the inert gas supply pipe 331) may have mutually different shapes or arrangements. The gas supply 30 may be configured to be able to supply another gas in addition to deuterium gas, hydrogen gas, and inert gas.

The exhauster 40 is provided in an exhaust port 41 that is formed in the side wall of an upper part of the manifold 12. The exhauster 40 has an exhaust path 42 connected to the exhaust port 41. The exhaust path 42 is provided with a pressure regulating valve 43 and a vacuum pump 44 in an order from an upstream side to a downstream side in the gas flow direction. The exhauster 40 operates the pressure regulating valve 43 and the vacuum pump 44 under the control of the controller 60, and adjusts the pressure in the processing chamber 10 by the pressure regulating valve 43 while sucking the gas in the processing chamber 10 by the vacuum pump 44.

The heater 50 has a cylindrical heater 51 surrounding the cylindrical body 11 on the radially outer side of the cylindrical body 11. The heater 51 heats each substrate W accommodated in the processing chamber 10 by heating the entirety of the side circumference of the processing chamber 10.

The controller 60 may be a computer including one or more processors 61, a memory 62, and an input/output interface and electronic circuits that are not illustrated. The processor 61 is one, or a combination of one or more selected from a CPU, an ASIC, an FPGA, a circuit including a plurality of discrete semiconductors, and the like. The memory 62 includes a volatile memory and a nonvolatile memory (for example, a compact disk, a DVD, a hard disk, a flash memory, and the like), and stores a program for operating the substrate processing apparatus 1, a recipe for process conditions of substrate processing, and the like. The processor 61 executes the program and the recipe stored in the memory 62 to thereby control each part of the substrate processing apparatus 1 and perform the substrate processing method described above.

### [Operation of the Substrate Processing Apparatus]

The operation of the substrate processing apparatus 1 in a case of performing the substrate processing method according to the embodiment will be described below. A case where the controller 60 executes the process illustrated in FIG. 2 will be described below as an example. The controller 60 can execute the processes illustrated in FIGS. 3 to 5 in the same manner as the processes illustrated in FIG. 2.

First, the controller 60 controls the elevating mechanism 21 to carry the boat 20 holding a plurality of substrates W into the processing chamber 10, and hermetically closes the opening at the lower end of the processing chamber 10 with the cap 15. Each substrate W is a substrate having a silicon nitride film on a surface thereof.

Next, the controller 60 controls the gas supply 30, the exhauster 40, and the heater 50 so as to execute the depressurization process S2. Specifically, the controller 60 controls the exhauster 40 to reduce the pressure in the processing chamber 10 from the first pressure P1 to the second pressure P2. The controller 60 controls the heater 50 to maintain the substrates W at the first temperature T1. The controller 60 controls the gas supply 30 to start deuterium gas supply into the processing chamber 10. As a result, the pressure in the processing chamber 10 is raised from the second pressure P2 to the third pressure P3.

Next, the controller 60 controls the gas supply 30, the exhauster 40, and the heater 50 so as to execute the temperature raising step S3. Specifically, the controller 60 controls the heater 50 to raise the temperature of the substrates W from the first temperature T1 to the second temperature T2. The controller 60 controls the exhauster 40 to maintain the pressure in the processing chamber 10 at the third pressure P3 while continuing to supply the deuterium gas into the processing chamber 10 by controlling the gas supply 30.

Next, the controller 60 controls the gas supply 30, the exhauster 40, and the heater 50 so as to execute the temperature maintaining step S4. Specifically, the controller 60 controls the heater 50 to maintain the temperature of the substrates W at the second temperature T2. The controller 60 controls the exhauster 40 to maintain the pressure in the processing chamber 10 at the third pressure P3 while continuing to supply the deuterium gas into the processing chamber 10 by controlling the gas supply 30. After a predetermined time has elapsed, the controller 60 controls the gas supply 30 to stop the supply of the deuterium gas into the processing chamber 10.

Next, the controller 60 controls the exhauster 40 and the heater 50 so as to execute the temperature lowering step S5. Specifically, the controller 60 controls the heater 50 to lower the temperature of the substrates W from the second temperature T2 to the first temperature T1. The controller 60 controls the exhauster 40 to reduce the pressure in the processing chamber 10 from the third pressure P3 to the second pressure P2.

Next, the controller 60 controls the gas supply 30, the exhauster 40, and the heater 50 so as to execute the pressure raising step S6. Specifically, the controller 60 controls the gas supply 30 to supply an inert gas into the processing chamber 10, and controls the exhauster 40 to stop exhausting the processing chamber 10 of gas. As a result, the pressure in the processing chamber 10 is raised from the second pressure P2 to the first pressure P1. The controller 60 controls the heater 50 to maintain the temperature of the substrates W at the first temperature T1.

Next, the controller 60 lowers the temperature of the substrate W to an unloading temperature, and then controls the elevating mechanism 21 to unload the boat 20 from the processing chamber 10. Thus, processing of the plurality of substrates W held on the boat 20 is completed.

### Examples

Examples in which it was confirmed to be possible to increase the deuterium concentration in a silicon nitride film by the substrate processing method according to the embodiment will be described.

In Examples, substrates having a silicon nitride film on a surface thereof were prepared, the prepared substrates were accommodated in the processing chamber 10 of the substrate processing apparatus 1 described above, and deuterium atoms were introduced into the silicon nitride film under the following conditions A to F. Next, the deuterium concentration in the silicon nitride film was measured by Secondary Ion Mass Spectrometry (SIMS).

### (Condition A)

Under the condition A, the prepared substrates were subjected to the pressure reducing step S2, the temperature raising step S3, the temperature maintaining step S4, the temperature lowering step S5, and the pressure raising step S6 in this order. In the pressure reducing step S2, the temperature of the substrates was maintained at 600° C., and the pressure in the processing chamber 10 was reduced from the open-air pressure to the base pressure without supply of deuterium gas and hydrogen gas into the processing chamber 10. In the temperature raising step S3, the temperature of the substrates was raised from 600° C. to 800° C., and the pressure in the processing chamber 10 was reduced from the base pressure to 12 kPa (90 Torr) without supply of deuterium gas and hydrogen gas into the processing chamber 10. In the temperature maintaining step S4, the temperature of the substrates was maintained at 800° C., and deuterium gas was continuously supplied into the processing chamber 10 throughout the entire period of the step to maintain the pressure in the processing chamber 10 at 12 kPa. In the temperature lowering step S5, the temperature of the substrates was lowered from 800° C. to 600° C., and the pressure in the processing chamber 10 was reduced from 12 kPa to the base pressure without supply of deuterium gas and hydrogen gas into the processing chamber 10. In the pressure raising step S6, the temperature of the substrates was maintained at 600° C., and inert gas was supplied into the processing chamber 10 to raise the pressure in the processing chamber 10 from the base pressure to the open-air pressure.

### (Condition B)

Under the condition B, hydrogen gas was continuously supplied into the processing chamber 10 throughout the entire period of the temperature raising step S3. Other particulars were the same as those under the condition A.

### (Condition C)

Under the condition C, deuterium gas was continuously supplied into the processing chamber 10 throughout the entire period of the temperature raising step S3. Other particulars were the same as those under the condition A.

### (Condition D)

Under the condition D, deuterium gas was continuously supplied into the processing chamber 10 throughout the entire period of the temperature lowering step S5. Other particulars were the same as those under the condition A.

### (Condition E)

Under the condition E, hydrogen gas was continuously supplied into the processing chamber 10 throughout the entire period of the temperature raising step S3, and deuterium gas was continuously supplied into the processing chamber 10 throughout the entire period of the temperature lowering step S5. Other particulars were the same as those under the condition A.

### (Condition F)

Under the condition F, deuterium gas was continuously supplied into the processing chamber 10 throughout the entire period of the temperature raising step S3, and deuterium gas was continuously supplied into the processing chamber 10 throughout the entire period of the temperature lowering step S5. Other particulars were the same as those under the condition A.

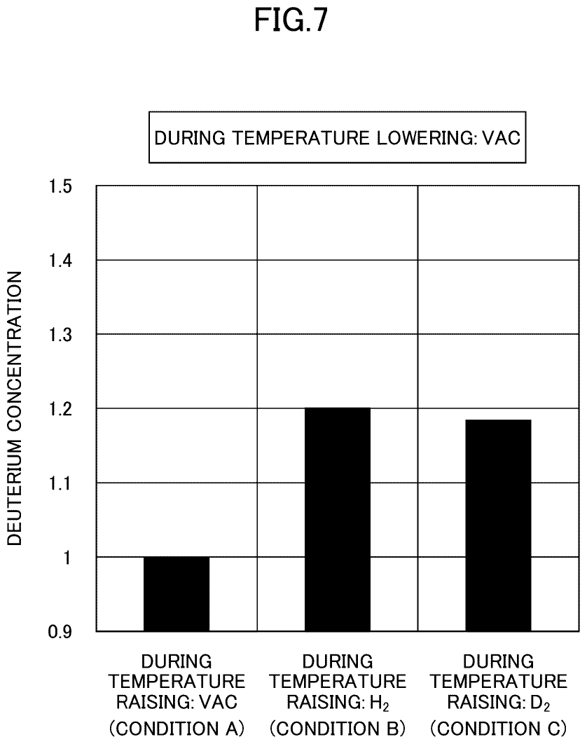

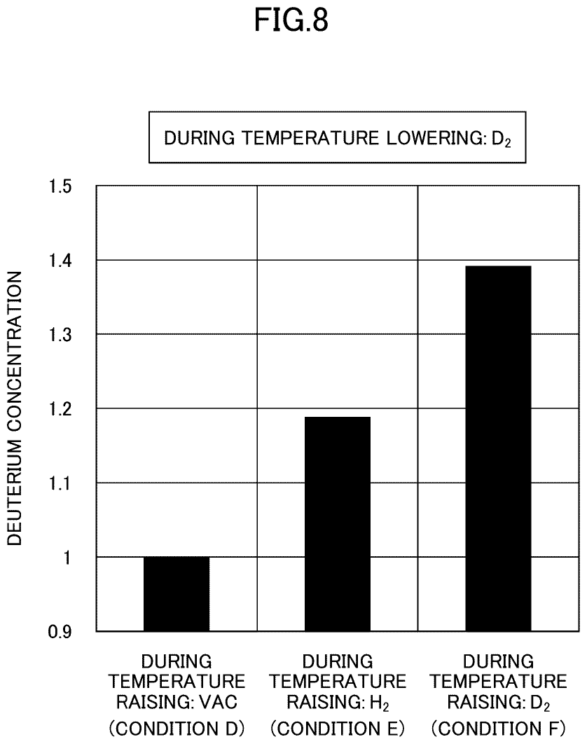

FIGS. 7 and 8 are graphs illustrating the results of measurement of the deuterium concentration in the silicon nitride films. FIG. 7 illustrates the deuterium concentration in the silicon nitride films in which deuterium atoms were introduced under the conditions A, B, and C. FIG. 8 illustrates the deuterium concentration in the silicon nitride films in which deuterium atoms were introduced under the conditions D, E, and F.

In FIG. 7, the left, center, and right graphs indicate the deuterium concentration in the silicon nitride films in which deuterium atoms were introduced under the conditions A, B, and C, respectively. FIG. 7 indicates the deuterium concentration in the silicon nitride films in which deuterium atoms were introduced under the conditions A, B, and C, as a ratio to the deuterium concentration in the silicon nitride film in which deuterium atoms were introduced under the condition A.

In FIG. 8, the left, center, and right graphs indicate the deuterium concentration in the silicon nitride films in which deuterium atoms were introduced under the conditions D, E, and F, respectively. FIG. 8 indicates the deuterium concentration in the silicon nitride films in which deuterium atoms were introduced under the conditions D, E, and F as a ratio to the deuterium concentration in the silicon nitride film in which deuterium atoms were introduced under the condition D.

As illustrated in FIG. 7, it can be seen that the deuterium concentration in the silicon nitride film was approximately 20% higher under the conditions B and C than under the condition A. This result indicates that it was possible to increase the deuterium concentration in the silicon nitride film by supplying hydrogen gas or deuterium gas into the processing chamber 10 in the temperature raising step S3.

As illustrated in FIG. 8, it can be seen that the deuterium concentration in the silicon nitride film was approximately 20% higher under the condition E than under the condition D, and that the deuterium concentration in the silicon nitride film was approximately 40% higher under condition F than under the condition D. From these results, it was indicated that it was possible to increase the deuterium concentration in the silicon nitride film by supplying hydrogen gas or deuterium gas into the processing chamber 10 in the temperature raising step S3. In particular, in a case of continuously supplying deuterium gas into the processing chamber 10 throughout the entire period of the temperature lowering step S5, it was indicated that it was possible to better increase the deuterium concentration in the silicon nitride film by supplying deuterium gas into the processing chamber 10 than by supplying hydrogen gas, in the temperature raising step S3.

It should be considered that the embodiments disclosed herein are exemplary in all respects and not restrictive. Various omissions, substitutions, and modifications are applicable to the above-described embodiments without departing from the scope and spirit of the appended claims.

In the above-described embodiments, the case where the insulating film is a silicon nitride film has been described, but the present disclosure is not limited to this. The insulating film may be a film, which is at least a partial constituent of a charge storage layer used in a memory cell. The insulating film may be a silicon oxide film or a silicon oxynitride film. The insulating film may contain hydrogen atoms in the film. In a case where the insulating film is a silicon oxide film, the insulating film may contain O—H bonds. In a case where the insulating film is a silicon oxynitride film, the insulating film may contain N—H bonds and O—H bonds.

In the above embodiment, the case where the substrate processing apparatus is a batch type apparatus for processing a plurality of substrates at a time has been described, but the present disclosure is not limited to this. For example, the substrate processing apparatus may be a single-wafer type apparatus for processing substrates one by one.

What is claimed is:

1. A substrate processing method, comprising:
preparing a substrate having an insulating film on a surface thereof;
raising a temperature of the substrate from a first temperature to a second temperature higher than the first temperature; and
maintaining the substrate at the second temperature,
wherein the raising of the temperature to the second temperature includes supplying either gas or both gases selected from a deuterium gas and a hydrogen gas to the substrate, and
the maintaining of the substrate at the second temperature includes supplying a deuterium gas to the substrate.

2. The substrate processing method according to claim 1,
wherein the either gas or both gases is continuously supplied throughout an entire period of the raising of the temperature to the second temperature.

3. The substrate processing method according to claim 2,
wherein the either gas or both gases is continuously supplied prior to start of the raising of the temperature to the second temperature.

4. The substrate processing method according to claim 1,
wherein the deuterium gas is continuously supplied throughout an entire period of the maintaining of the substrate at the second temperature.

5. The substrate processing method according to claim 1, further comprising:
lowering the temperature of the substrate from the second temperature to the first temperature,
wherein the lowering of the temperature to the first temperature includes supplying the deuterium gas to the substrate.

6. The substrate processing method according to claim 5,
wherein the deuterium gas is continuously supplied throughout an entire period of the lowering of the temperature to the first temperature.

7. The substrate processing method according to claim 1,
wherein the either gas or both gases is the deuterium gas.

8. The substrate processing method according to claim 1,
wherein the either gas or both gases is the hydrogen gas.

9. The substrate processing method according to claim 1,
wherein the either gas or both gases is a mixed gas of the deuterium gas and the hydrogen gas.

10. The substrate processing method according to claim 1,
wherein the insulating film is a silicon nitride film.

11. A substrate processing apparatus, comprising:
a processing chamber in which a substrate having an insulating film on a surface thereof is accommodated;
a gas supply configured to supply a gas into the processing chamber;
a heater configured to heat the substrate accommodated in the processing chamber; and
a controller,
wherein the controller is configured to control the heater to perform:
raising a temperature of the substrate from a first temperature to a second temperature higher than the first temperature in the processing chamber; and
maintaining the substrate at the second temperature in the processing chamber,
the controller is configured to control the gas supply to supply either gas or both gases selected from a deuterium gas and a hydrogen gas to the substrate in the raising of the temperature to the second temperature, and
the controller is configured to control the gas supply to supply the deuterium gas to the substrate in the maintaining of the substrate at the second temperature.
